(19) United States
(12) Patent Application Publication
(10) Pub. No.: US 2015/0145055 A1
(43) Pub. Date: May 28, 2015

(54) HIGH VOLTAGE DEVICES AND METHOD OF MANUFACTURING THE SAME

(71) Applicant: Samsung Electronics Co., Ltd., Suwon-si (KR)

(72) Inventor: Jong-Sam KIM, Seongnam-si (KR)

(21) Appl. No.: 14/511,162

(22) Filed: Oct. 9, 2014

(30) Foreign Application Priority Data
Nov. 23, 2013 (KR) 10-2013-0146283

(51) Int. Cl. H01L 23/00; H01L 21/768; H01L 27/088

(52) U.S. Cl. CPC H01L 24/85; H01L 27/088; H01L 21/768; H01L 2224/42; H01L 2224/85; H01L 2924/01029
USPC 257/368; 438/618

(57) ABSTRACT

Disclosed is a high voltage device including a substrate structure having a high voltage transistor and a lower wiring connected to the high voltage transistor, a linker structure having a supplemental insulation pattern on the substrate structure and an interconnecting linker penetrating through the supplemental insulation pattern and connected to the lower wiring, an insulation interlayer pattern on the supplemental insulation pattern, and an upper wiring structure penetrating through insulation interlayer pattern and connected to the interconnecting linker. The thickness of the inter-metal dielectric layer between the upper and the lower wirings is increased to thereby improve the insulation characteristics of the inter-metal dielectric layer. As a result, the breakdown voltage and the current leakage characteristics of the high voltage device are improved.

### CROSS-REFERENCE TO RELATED APPLICATIONS

This application claims the benefit of Korean Patent Application No. 10-2013-0146283 filed on Nov. 28, 2013 in the Korean Intellectual Property Office, the disclosure of which is incorporated herein in its entirety by reference.

### BACKGROUND

1. Field

Example embodiments relate to a high voltage device and a method of manufacturing the same, and more particularly, to a high voltage device having copper wirings and a method of manufacturing the same.

2. Description of the Related Art

When integrated circuit devices directly control an external system requiring high voltage power, a high voltage device is necessarily installed in the integrated circuit device.

For example, a control device for a power control system such as a switching power supply and a motor driver, a central processing device for an automatic semiconductor system and a drive IC for a network system or a display system usually require the high voltage device for controlling the external system as well as a low voltage device for processing the internal signals.

The integrated circuit devices usually includes a plurality of transistors on a semiconductor substrate and a plurality of wiring structures connected with the transistors through insulation interlayers covering the transistors. The low voltage device and the high voltage device may be arranged on the same substrate and be separated from each other by an insulation area such as a junction termination portion. Further, the low voltage device and the high voltage device may also be connected to the wiring structures through a via-contact or a contact plug.

In some embodiments, the wiring structure may include metal wirings electrically separated by insulation interlayers and interconnectors such as contact plugs penetrating through the insulation interlayers and making contact with the metal wirings. Copper has been widely used for the metal wirings due to the relatively high melting point and the relatively low specific electric resistance.

The high voltage device generally requires a breakdown voltage higher than the allowable high voltage thereof. However, as the application area of the high voltage devices has been recently enlarged used in various fields such as a display drive IC (DDI) and a motor driver IC (MDI), the high voltage devices are desirable to be operated under much higher voltages than ever before. For those reasons, the breakdown voltage defect has been more frequently found in a recent high voltage device in which the breakdown voltage becomes under the allowable high voltage. For example, the recent high voltage device tends to fail in the time dependent dielectric breakdown (TDDB) test during the reliability test for the high voltage device.

The breakdown voltage defect of the high voltage device is known to be caused by the insufficient dielectric constant of the insulation interlayer with respect to the allowable high voltage applied to the high voltage device. Thus, the thickness of the insulation interlayer of the high voltage device may need to be increased so as to increase the dielectric constant thereof. However, an increase in the thickness of the insulation interlayer generally causes the increase of the aspect ratio of a via hole in a damascene process for forming the copper wiring in the insulation interlayer, which deteriorates the uniformity of the copper wirings.

Accordingly, there is still a need for an improved high voltage device having an insulation interlayer of which the dielectric constant is sufficiently high to the applied high voltage, thereby substantially reducing the breakdown voltage defect.

### SUMMARY

Example embodiment of the present inventive concept provides a high voltage device having an insulation interlayer of which the thickness is increased and having a double interconnector, thereby preventing the breakdown voltage defect without deteriorating the uniformity of the wirings.

According to some example embodiments, there is provided a high voltage device including a substrate structure having a high voltage transistor and a lower wiring connected to the high voltage transistor, a linker structure having a supplemental insulation pattern on the substrate structure and an interconnecting linker penetrating through the supplemental insulation pattern and making contact with the lower wiring, an insulation interlayer pattern on the supplemental insulation pattern and an upper wiring structure penetrating through insulation interlayer pattern and making contact with the interconnecting linker.

In an example embodiment, the supplemental insulation pattern may include an oxide pattern having an opening and the interconnecting linker includes a plug structure disposed in the opening and comprising a conductive metal.

In an example embodiment, the interconnecting linker may include a single damascene structure comprising copper (Cu).

In an example embodiment, the high voltage device may further include a lower barrier layer interposed between the interconnecting linker in the opening and the supplemental insulation pattern so that the interconnecting linker may be enclosed by the lower barrier layer in the opening.

In an example embodiment, the insulation interlayer pattern may include a first insulation pattern that may be arranged on the supplemental insulation pattern and may have a via hole through which the interconnecting linker may be exposed and a second insulation pattern that may be arranged on the first insulation pattern and has a line-shaped trench communicating with the via hole. The upper wiring structure may include a via structure disposed in the via hole and connected to the interconnecting linker and an upper wiring disposed in the line-shaped trench and connected to the via structure.

In an example embodiment, the upper wiring structure may include a dual damascene structure in which the via structure and the upper wiring may be integrally formed in one body.

In an example embodiment, the insulation interlayer pattern may include an oxide pattern and the via structure and the upper wiring includes copper (Cu).

In an example embodiment, the high voltage device may further include an upper barrier layer interposed between the insulation interlayer pattern and the upper wiring structure and between the upper wiring structure and the interconnecting linker, so that the upper wiring structure may be enclosed by the upper barrier layer in the trench and the via hole.

According to some example embodiments, there is provided a method of manufacturing the above high voltage device. A substrate structure may be formed to have a high voltage transistor and a lower wiring connected to the high voltage transistor. A linker structure may be formed on the substrate structure in such a manner that the linker structure may have a supplemental insulation pattern on the substrate structure and an interconnecting linker penetrating through the supplemental insulation pattern and making contact with the lower wiring. An insulation interlayer pattern may be formed on the supplemental insulation pattern, and an upper wiring structure may be formed to penetrate through insulation interlayer pattern and make contact with the interconnecting linker.

In an example embodiment, the linker structure may be formed as follows. A supplemental insulation layer may be formed on the substrate structure, and the supplemental insulation layer may be partially removed by an etching process to thereby form a supplemental insulation pattern having an opening through which the lower wiring is exposed. Thereafter, a first conductive layer may be formed on the supplemental insulation pattern to a thickness to fill the opening. Then, the first conductive layer may be planarized until an upper surface of the supplemental insulation pattern is exposed, leaving a portion of the first conductive layer in the opening.

In an example embodiment, prior to forming the first conductive layer on the supplemental insulation pattern, a preliminary lower barrier layer may be further formed on the supplemental insulation pattern along a surface profile of the opening.

In an example embodiment, the first conductive layer may be formed by one of a reflow process, an electroplating process and a deposition process.

In an example embodiment, the insulation interlayer pattern may be formed as follows. First and second insulation layers may be sequentially formed on the linker structure. Then, the first and the second insulation layers may be partially removed by an etching process, thereby forming first and second insulation patterns having a preliminary via hole through which the interconnecting linker is exposed. Thereafter, the second insulation pattern may be additionally removed by another etching process around the preliminary via hole, so that the preliminary via hole in the second insulation pattern may be formed into a trench having a width greater than the preliminary via hole and the preliminary via hole in the first insulation pattern may be formed into a via hole.

In an example embodiment, the upper wiring structure may be formed as follows. A preliminary upper barrier layer may be formed on the insulation interlayer pattern along a surface profile of the trench and the via hole, and a second conductive layer may be formed on the preliminary upper barrier to a thickness to fill the via hole and the trench. Then, the second conductive layer may be planarized until an upper surface of the insulation interlayer pattern may be exposed, so that the second conductive layer may remain in the via hole and the trench to thereby simultaneously form a via structure in the via hole and an upper wiring in the trench.

In an example embodiment, the lower wiring, the interconnecting linker, the via structure and the upper wiring may include one of copper and copper alloy.

According to example embodiments of the present inventive concept, the supplemental insulation pattern as well as the insulation interlayer pattern may be interposed between the upper wiring and the lower wiring of the high voltage device, so that the thickness of the inter-metal dielectric layer may be sufficiently increased between the upper wiring and the lower wiring. Therefore, although relatively high voltages may be applied to the high voltage device, the high voltage device may sufficiently require the current leakage characteristics and the breakdown voltage characteristics.

In some embodiments, a single damascene structure may be additionally provided between the upper wiring structure and the lower wiring structure through an additional process, the thickness of the inter-metal dielectric layer may be increased between the upper wiring structure and the lower wiring structure without much changes to the conventional processes for forming the upper wiring structure and the lower wiring structure. Accordingly, the current leakage characteristics and the breakdown voltage characteristics of the high voltage device may be significantly improved without much changes to the conventional processes.

Further, the opening of the supplemental insulation pattern for the interconnecting linker may be additionally provided with the high voltage device by an additional process, the thickness of the inter-metal dielectric layer between the upper wiring and the lower wiring may be increased without a substantial increase in the aspect ratio of the trench and the via hole, thereby sufficiently preventing the process defects such as voids and overhangs of the interconnector making contact with the upper wiring and the lower wiring in spite of the increased thickness of the inter-metal dielectric layer.

### BRIEF DESCRIPTION OF THE DRAWINGS

Example embodiments will be more clearly understood from the following detailed description taken in conjunction with the accompanying drawings.

FIG. 1 is a cross-sectional view illustrating a high voltage device in accordance with an example embodiment of the present inventive concept;

FIGS. 2A to 2L are cross-sectional views illustrating processing steps for method of manufacturing the high voltage device shown in FIG. 1; and

FIG. 3 is a perspective view illustrating a driving circuit package including the high voltage device shown in FIG. 1 in accordance with an example embodiment of the present inventive concept.

### DETAILED DESCRIPTION OF THE EMBODIMENTS

Various example embodiments will be described more fully hereinafter with reference to the accompanying drawings, in which some example embodiments are shown. The present invention may, however, be embodied in many different forms and should not be construed as limited to the example embodiments set forth herein. Rather, these example embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings. In the following disclosed example embodiments, an opening through which a lower wiring is exposed is referred to as via hole and an opening that is communicated with the via hole and in which wirings are formed is referred to as trench.

High Voltage Device and Manufacturing Method Thereof.

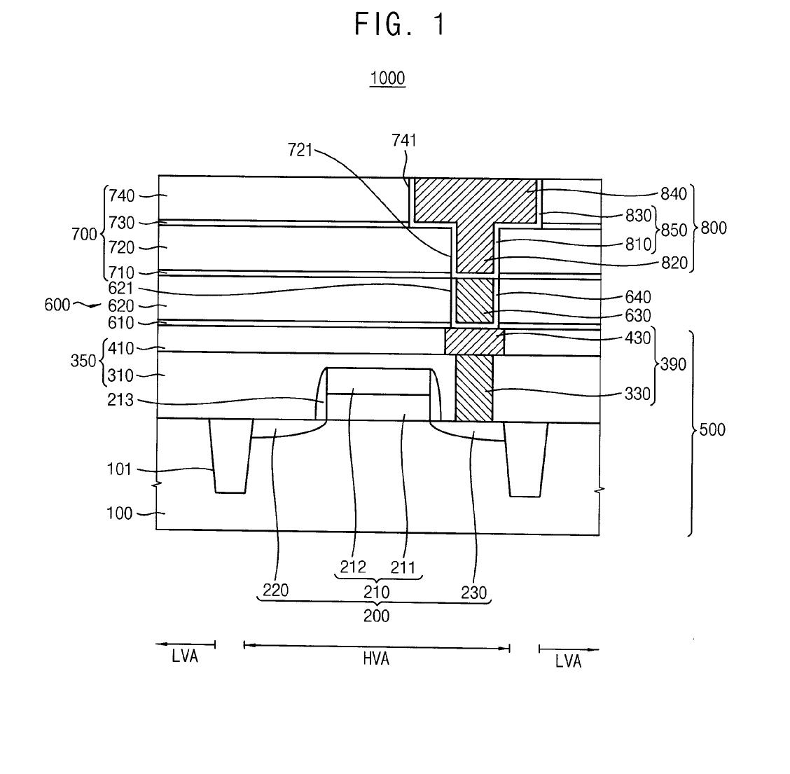

FIG. 1 is a cross-sectional view illustrating a high voltage device in accordance with an example embodiment of the present inventive concept.

Referring to FIG. 1, a high voltage device 1000 in accordance with an example embodiment of the present inventive concept may include a substrate structure 500 having a high voltage transistor 200 and a lower wiring 430 connected to the high voltage transistor 200, a linker structure 600 having a supplemental insulation pattern 620 on the substrate structure 500 and an interconnecting linker 630 penetrating through the supplemental insulation pattern 620 and making contact with the lower wiring 430, an insulation interlayer pattern 700 on the linker structure 600, and an upper wiring structure 800 penetrating trough the insulation interlayer pattern 700 and making contact with the interconnecting linker 630.

For example, the substrate structure 500 may include a semiconductor substrate 100 such as a wafer on which a plurality of high and low voltage transistors that may be arranged.

Thus, the substrate 100 may be defined into a high voltage area (HVA) in which the high voltage devices may be arranged and a low voltage area (LVA) in which the low voltage devices may be arranged. A junction termination portion (not shown) may be provided on the substrate 100 between the HVA and the LVA so as to electrically insulate the HVA and LVA from each other. A plurality of level shift devices may be selectively provided in the junction termination portion for transmitting signals from low voltage devices to the high voltage devices.

A plurality of the high voltage devices may be arranged in the HVA of the substrate 100 and a plurality of the low voltage devices may be arranged in the LVA of the substrate 100. In some embodiments, the gate insulation layer of the high voltage device may have a greater thickness than that of the low voltage device. In FIG. 1, the high voltage device in the HVA of the substrate 100 may be exemplarily illustrated and the low voltage device in the LVA will be omitted for convenience's sake.

The HVA may include an active region (not shown) defined by a device isolation layer 101 and the high voltage transistor 200 may be arranged on the active region of the HVA of the substrate 100.

For example, a device isolation trench (not shown) may be formed on the substrate 100 to define the active region and insulation materials may be filled into the device isolation trench, thereby forming the device isolation layer 101 around the active region. The high voltage transistors 200 may be arranged on the active regions of the substrate 100 and the neighboring high voltage structures 200 may be electrically insulated from each other by the device isolation layer 101.

The high voltage transistor 200 may include, for example, a dynamic random access memory (DRAM) device, a flash memory device and an image sensor.

The high voltage transistor 200 may include a high voltage gate structure 210 and source and drain regions 220 and 230 at surface portions of the substrate 100 adjacent to the high voltage gate structure 210.

The high voltage gate structure 210 may include a high voltage gate insulation layer 211 and a high voltage gate conductive layer 212. The high voltage gate insulation layer 211 may comprise oxide and the high voltage gate conductive layer 212 may comprise polysilicon such as doped polysilicon or a conductive material such as a metal having good conductivity. In some embodiments, the high voltage gate insulation layer 211 may have a thickness greater than a low voltage gate insulation layer (not shown), so that the high voltage transistor 200 may function as a switching element in spite of a high gate voltage.

Impurities may be implanted onto the surface portions of the substrate 100 adjacent to the high voltage gate structure 210, so that the source region 220 and the drain region 230 may be provided adjacent to the high voltage gate structure 210 and may be connected with the external environment of the high voltage gate structure 210. That is, the high voltage gate structure 210 may be electrically communicated with surroundings through the source and drain regions 220 and 230. For example, a capacitor may be electrically connected to the source region 220 via a source plug (not shown) and an external signal line may be electrically connected to the drain region 230 via a drain plug 330. External signals may be applied to the source plug and the drain plug 330 through a source wiring (not shown) and a drain wiring (or the lower wiring) 430, which may be respectively arranged over the source plug and the drain plug 330. The source wiring and the drain wiring 430 may constitute the lower wiring adjacent to the high voltage transistor 200.

However, FIG. 1 exemplarily illustrates just the drain wiring 430 for convenience's sake, so that the source wiring may also be provided with the high voltage device 1000, as would be readily understood by those skilled in the art. In some embodiments, the source wiring and the drain wiring 430 may be separately provided on different insulation interlayers. For those reasons, the drain wiring 430 is used for a representative of the lower wiring and the same reference numeral 430 may be designated to the drain wiring and the lower wiring.

For example, a first lower insulation pattern 310 may be formed on the substrate 100 to a sufficient thickness to cover the high voltage gate structure 210 and the drain plug 330 may penetrate the first lower insulation pattern 310 until the drain plug 330 may contact the drain region 230. A second lower insulation pattern 410 may be arranged on the first lower insulation pattern 310 with which a line shaped trench may be provided such that the drain plug 330 may be exposed through the trench. The lower wiring 430 may be disposed in the trench and make contact with the drain plug 330. The neighboring drain wirings 430 may be electrically insulated from each other by the second lower insulation pattern 430.

The drain plug 330 and the lower wiring 430 may be separately formed by a respective process or may be integrally formed together by a single process such as a dual damascene process. The drain plug 330 and the lower wiring 430 may further include a drain barrier layer (not shown), respectively, so as to prevent the diffusion of the conductive materials of the drain plug 330 and the lower wiring 430 at a boundary surface between the drain plug 330 and the first lower insulation pattern 310 and between the lower wiring 430 and the second lower insulation pattern 410. Further, an additional impurity layer (not shown) may be interposed between the drain plug 330 and the drain region 230 for improving the ohmic characteristics.

The drain plug 330 and the lower wiring 430 may be formed of polysilicon such as doped polysilicon or a conductive material such as a metal having high electrical conductivity such as tungsten (W) and copper (Cu). In the present example embodiment, the drain plug 330 may comprise polysilicon and the lower wiring 430 may comprise copper (Cu) having a low specific electrical resistance.

The upper wiring structure 800 including an upper wiring 840 may be provided on the substrate structure 500. Further, the linker structure 600 may be interposed between the upper wiring structure 800 and the lower wiring 430. Thus, the upper wiring 840 may be electrically connected to the lower wiring 430 via the linker structure 600.

The linker structure 600 may provide a sufficient vertical distance between the upper wiring 840 and the lower wiring 430 and an optional additional insulation interlayer pattern disposed therebetween, thereby increasing the thickness of the insulation interlayer between the upper wiring 840 and the lower wiring 430. Therefore, a dielectric bulk having a sufficient dielectric constant may be interposed between the upper wiring 840 and the lower wiring 430. As a result, the leakage current may be sufficiently prevented between the upper wiring 840 and the lower wiring 430 although a relatively high voltage may be applied between the upper wiring 840 and the lower wiring 430, thereby maintaining sufficient breakdown voltage characteristics of the high voltage device 1000.

In the present example embodiment, the linker structure 600 may include a supplemental insulation pattern 620 that may be positioned on the substrate structure 500. Further, the linker structure 600 may include an opening 621 extending therethrough, through which the lower wiring 430 may be exposed. An interconnecting linker 630 is disposed within the opening 621. The interconnecting linker 60 extends through the supplemental insulation pattern 620 and contacts the lower wiring 430.

The supplemental insulation pattern 620 may comprise the same materials as the insulation interlayer pattern 700 such that the supplemental insulation pattern 620 may function as an inter-metal dielectric layer pattern between the upper wiring 840 and the lower wiring 430 together with the insulation interlayer pattern 700. Accordingly, the thickness of the inter-metal dielectric layer pattern may be increased as much as the thickness of the supplemental insulation pattern 620 between the upper wiring 840 and the lower wiring 430, as compared with the conventional inter-metal dielectric layer pattern.

According to the conventional high voltage device with which no linker structure may be provided, the insulation interlayer pattern may function as the inter-metal dielectric layer pattern between the upper wiring and the drain wiring. Thus, the insulation characteristics of the insulation interlayer pattern is not sufficient for the relatively high voltage between the upper wiring and the drain wiring, thereby generating the leakage current between the upper wiring and the drain wiring. As a result, the breakdown voltage of the conventional high voltage device becomes lower than the high voltage applied to the conventional high voltage device.

However, according to the present inventive high voltage device 1000, the supplemental insulation pattern 620 may be additionally arranged between the upper wiring 840 and the lower wiring 430 and function as the inter-metal dielectric layer pattern between the upper wiring 840 and the lower wiring 430 together with the insulation interlayer pattern 700. Therefore, the supplemental insulation pattern 620 may supplement the inter-metal dielectric layer pattern between the upper wiring 840 and the lower wiring 430 and may increase the thickness of the inter-metal dielectric layer pattern sufficiently for the high voltage applied between upper wiring 840 and the lower wiring 430.

Therefore, the thickness of the supplemental insulation pattern 620 may be variously varied according to the high voltage that may be applied between the upper wiring 840 and the lower wiring 430.

For example, when the high voltage device 1000 is used for a control device of a motor driving system or a drive chip of a display driving circuit, the supplemental insulation pattern 620 may have a relatively large thickness because relatively high voltage may be applied to the motor driving system and the display driving circuit. Otherwise, when the high voltage device 1000 is used as a driving circuit for driving a memory cell, the supplemental insulation pattern 620 may have a relatively small thickness because relatively low voltage may be applied to the memory cell.

The supplemental insulation pattern 620 may comprise an insulation material having a low dielectric constant, so that RC signal delay and signal interference may be sufficiently prevented between the upper wiring 840 and the lower wiring 430 as well as reducing the power consumption of the high voltage device 1000.

In some embodiments, the supplemental insulation pattern 620 may comprise low-k organic polymer or oxide doped with impurities. For example, examples of the oxide doped with impurities may include fluorine-doped oxide, carbon-doped oxide, silicon oxide, hydrogen silsesquioxane (HSQ, SiO:H), methyl silsesquioxane (MSQ, SiO:CH3), amorphous hydrogenated silicon oxycarbide (a-SiOC:H), etc. These may be used alone or in combinations thereof. Examples of the low-k organic polymer may include polyallylether polymer, cyclic fluoride polymer, siloxane copolymers, fluorinated polyallylether polymer, polypentafluorostylene polymer, polytetrafluorostylene polymer, fluorinated polyimide polymer, fluorinated polynaphthalene polymer, polycide polymer, etc. These may be used alone or in combinations thereof.

In the present example embodiment, a supplemental insulation layer may be formed on the substrate structure 500 by a deposition process or a spin coating process. Then, the supplemental insulating layer may then be patterned by a dry etching process to have the opening 621 through which the lower wiring 430 may be exposed, thereby forming the supplemental insulation pattern 620.

In some embodiments, a first etch stop pattern 610 may be further interposed between the substrate structure 500 and the supplemental insulation pattern 620, thereby preventing the lower wiring 430 from being damaged in the dry etching process.

For example, a first etch stop layer (not shown) may be exposed through the opening 621 over the lower wiring 430, and then the first etch stop layer may be partially removed from the substrate structure 500 by an etching process such as an additional reactive ion etching process until the lower wiring 430 is exposed through the opening 621. As a result, the first etch stop layer may be formed into the first etch stop pattern 610 through which the lower wiring 430 may be exposed. Accordingly, the first etch stop pattern 610 may be interposed just between the substrate structure 500 and the supplemental insulation pattern 620.

The interconnecting linker 630 may include a plug structure disposed in the opening 621 such that the lower wiring 430 may make contact with the interconnecting linker 630 in the opening 621.

For example, the interconnecting linker 630 may comprise a conductive material such as a metal having good electrical conductivity and low electrical resistance such as tungsten (W), tantalum (Ta), aluminum (Al) and copper (Cu), and thus may function as an interconnector between the upper wiring 840 and the lower wiring 430. In the present example embodiment, the interconnecting linker 630 may include a single damascene structure comprising copper (Cu), so that the surface resistance between the lower wiring 430 and the interconnecting linker 630.

A lower barrier layer 640 may be additionally provided on a sidewall of the opening 621 and on a portion of the lower wiring 430 exposed through the opening 621, so that the interconnecting linker 630 may be enclosed by the lower bather layer 640. The lower barrier layer 640 may substantially prevent the low resistive metal of the interconnecting linker 630 from being diffused into the supplemental insulation pattern 620. In some embodiments, when the interconnecting linker 630 has a single damascene structure, the copper (Cu) of the interconnecting linker 630 may be substantially prevented from being diffused into the supplemental insulation pattern 620 by the lower barrier layer 640 in spite of the high diffusion property of copper (Cu).

Then, the insulation interlayer pattern 700 may be arranged on the linker structure 600 and the upper wiring structure 800 may be arranged through the insulation interlayer pattern 700 such that the interconnecting linker 630 may make contact with the upper wiring structure 800.

For example, the insulation interlayer pattern 700 may include a first insulation pattern 720 that may be arranged on the supplemental insulation pattern 620 and have a via hole 721 through which the interconnecting linker 630 may be exposed and a second insulation pattern 740 that may be arranged on the first insulation pattern 720 and have a line-shaped trench 741 in communication with the via hole 721.

The insulation interlayer pattern 700 may comprise a low-k material having good thermal stability, thereby preventing the signal delay and interference between the lower wiring 430 and the upper wiring 840 and reducing power consumption of the high voltage device 1000. In the present example embodiment, the first and the second insulation patterns 720 and 740 may comprise the same materials as the supplemental insulation pattern 620. That is, the insulation interlayer pattern 700 may comprise the low-k organic polymers or the oxides doped with impurities.

The insulation interlayer pattern 700 may electrically insulate the upper wiring structure 800 from the lower substrate structure 500 and the neighboring upper wiring structures 800 may be electrically insulated from each other by the insulation interlayer pattern 700.

The upper wiring structure 800 may include a via structure 820 making contact with the interconnecting linker 630 and the upper wiring 840 making contact with the via structure 820 and extending along a line. In the present example embodiment, the via structure 820 may include a contact plug penetrating through the first insulation pattern 720 and the upper wiring 840 may have different shapes at various positions. Thus, the neighboring via structures 820 may be insulated from each other by the first insulation pattern 720 and the neighboring upper wirings 840 may be insulated from each other by the second insulation pattern 740.

That is, the via structure 820 may be provided in the via hole 721 of the first insulation pattern 720 and the upper wiring 840 may be provided in the trench 741 of the second insulation pattern 740. The via hole 721 may be in communication with the trench 741 and the width of the trench 741 may be greater than that of the via hole 721.

The via structure 820 and the upper wiring 840 may be separately formed with the high voltage device 1000 by a respective process or be integrally formed together by a single process.

The via structure 820 and the upper wiring 840 may be formed of a material having good electrical conductivity and low electrical resistance. Example of the materials for forming the via structure 820 and the upper wiring 840 may include aluminum (Al), copper (Cu), gold (Ag), silver (Au), tungsten (W), molybdenum (Mo), etc. These may be used alone or in combinations thereof.

In the present example embodiment, the via structure 820 and the upper wiring 840 may comprise copper (Cu) having relatively high melting point and relatively low specific resistance. A single damascene structure may be provided as the via structure 820 and the upper wiring 840.

A first upper barrier layer 810 may be further provided on a sidewall of the via hole 721 and on the interconnecting linker 630 expose through the via hole 721, so that the via structure 820 may be enclosed by the first upper barrier layer 810. In addition, a second upper barrier layer 830 may be further provided on a sidewall of the trench 741 and on the second insulation pattern 720 expose through the trench 741, so that the upper wiring 840 may be enclosed by the second upper barrier layer 830. The first and the second barrier layers 810 and 830 may substantially prevent the low resistive metal of the via structure 820 and the upper wiring 840 from being diffused into the insulation interlayer pattern 700.

In the present example embodiment, the via structure 820 and the upper wiring 840 may be integrally formed as a single damascene structure. In this case, the first and the second upper barrier layers 810 and 830 may be provided as a single upper barrier layer 850.

In addition, a second etch stop pattern 710 may be further interposed between the supplemental insulation pattern 620 and the first insulation pattern 720 and a third etch stop pattern 730 may be further interposed between the first insulation pattern 720 and the second insulation pattern 740.

The second etch stop pattern 710 may substantially prevent the interconnecting linker 630 from being damaged in an etching process for forming the via hole 721 and the third etch stop pattern 730 may indicate a terminal point of an etching process for forming the trench 741. Therefore, the terminal point of the etching process for forming the trench 741 may be accurately controlled by the third etch stop pattern 730.

A capping layer (not shown) may be further provided on the upper wiring structure 800 and a passivation layer (not shown) may be further provided on the capping layer for the high voltage device 1000. In a modified example embodiment, additional metal wirings may be provided on the upper wiring structure 800, so that the upper wiring structure 800 may be provided as a multilayer structure.

According to the present example embodiment of the high voltage device, the supplemental insulation pattern 620 as well as the insulation interlayer pattern 700 may be provided between the upper wiring structure 800 and the lower wiring 430, so that the thickness of the inter-metal dielectric layer may be increased between the upper wiring 840 and the lower wiring 430. Therefore, the leakage current may be sufficiently prevented between the upper wiring 840 and lower wiring 430 although relatively high voltage may be applied between the upper wiring 840 and the lower wiring 430. As a result, thus the breakdown voltage of the high voltage device 1000 may be maintained higher than the applied high voltage thereto.

When the thickness of the insulation interlayer pattern 700 may be increased for increasing the dielectric constant of the insulation interlayer pattern 700 in place of providing the supplemental insulation pattern 620, the aspect ratio of the via hole 721 may be inevitably increased, which may cause various processing defects such as voids and overhangs in the via structure 820 between the upper wiring 840 and the lower wiring 430.

However, according to the example embodiments of the present inventive concept, the supplemental insulation pattern 620 and the interconnecting linker 630 may be additionally provided between the upper wiring 840 and the lower wiring 430 in addition to the insulation interlayer pattern 700 and the via structure 820. Therefore, the thickness of the inter-metal dielectric layer may be sufficiently increased between the upper wiring 840 and the lower wiring 430 without a substantial increase in the thickness of the insulation interlayer pattern 700 and without any increase of the via hole 721. Accordingly, the upper wiring 840 and the lower wiring 430 may be connected with each other without any process defects of an interconnector therebetween, thereby increasing the operational reliability of the high voltage device 1000.

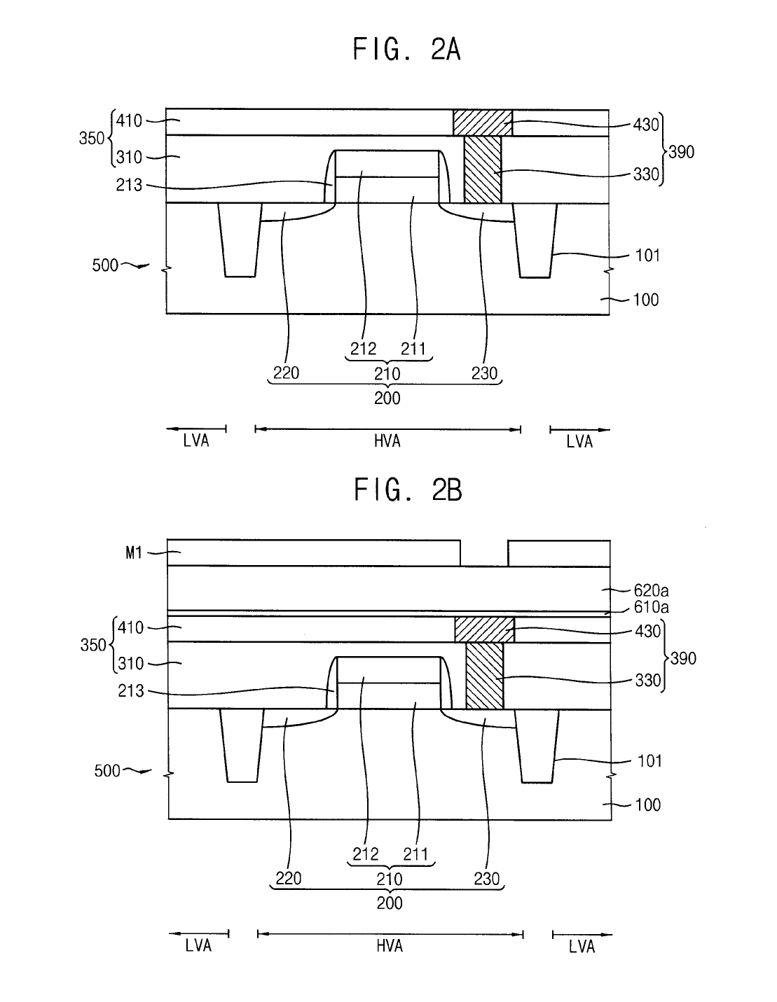

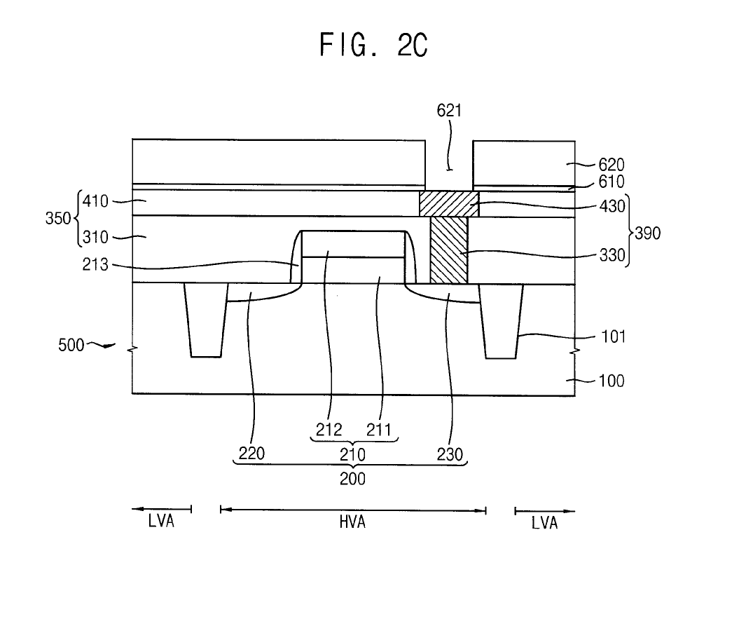

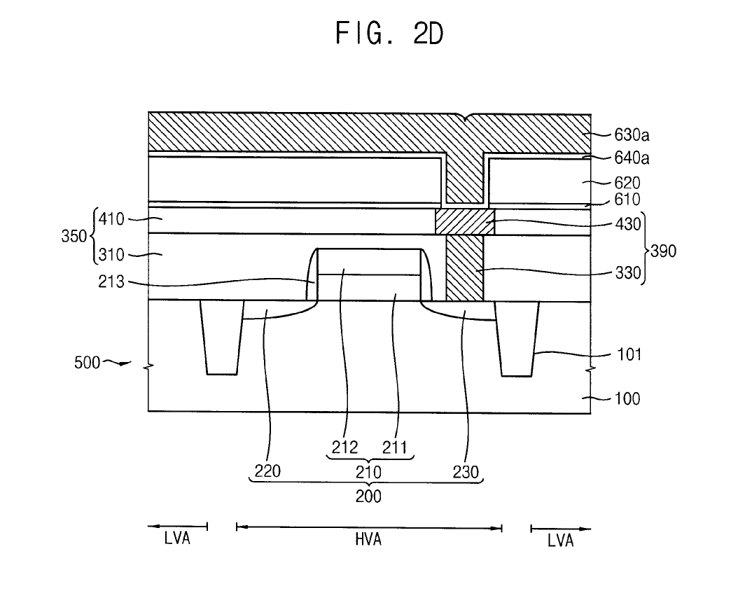

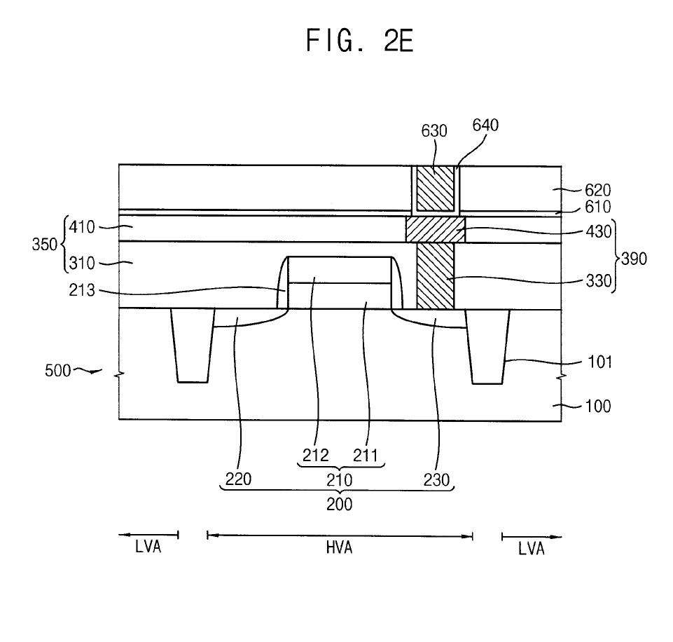

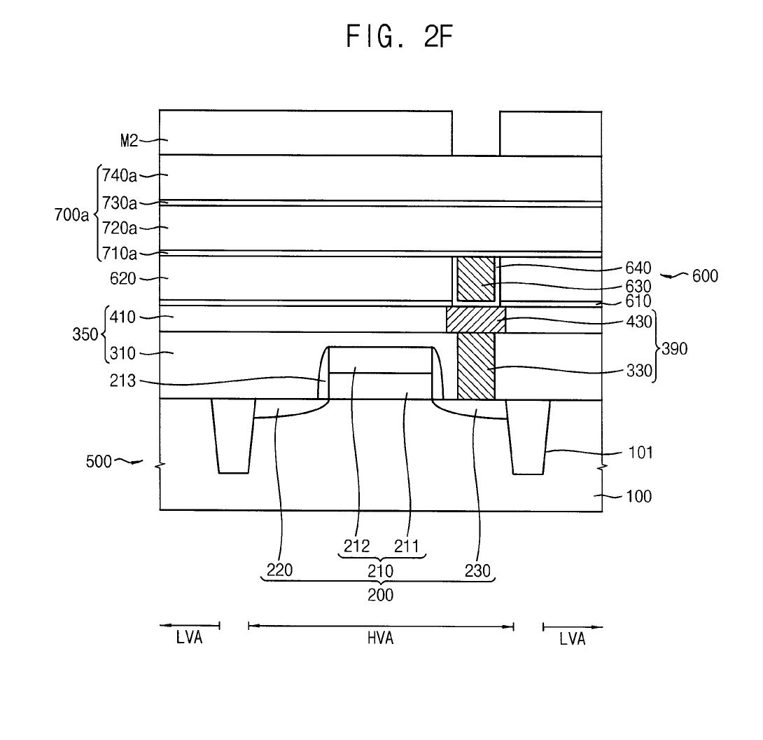

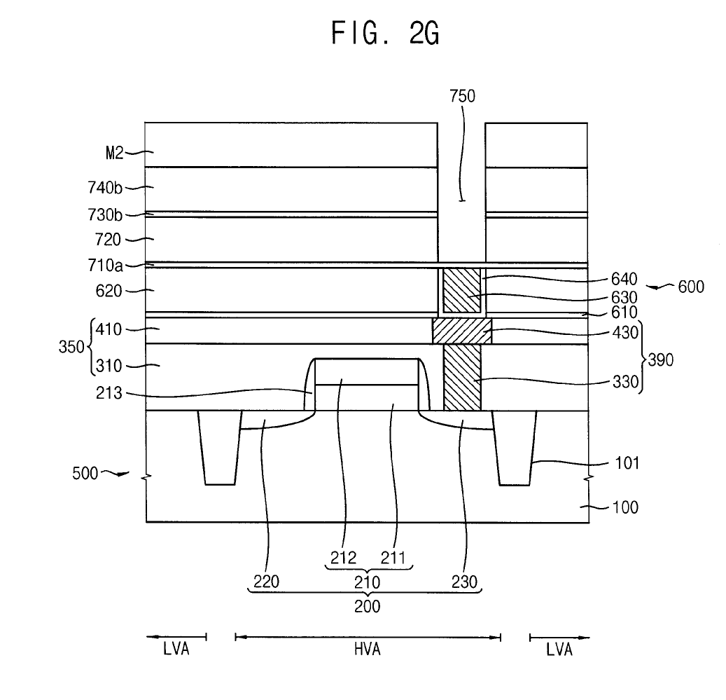

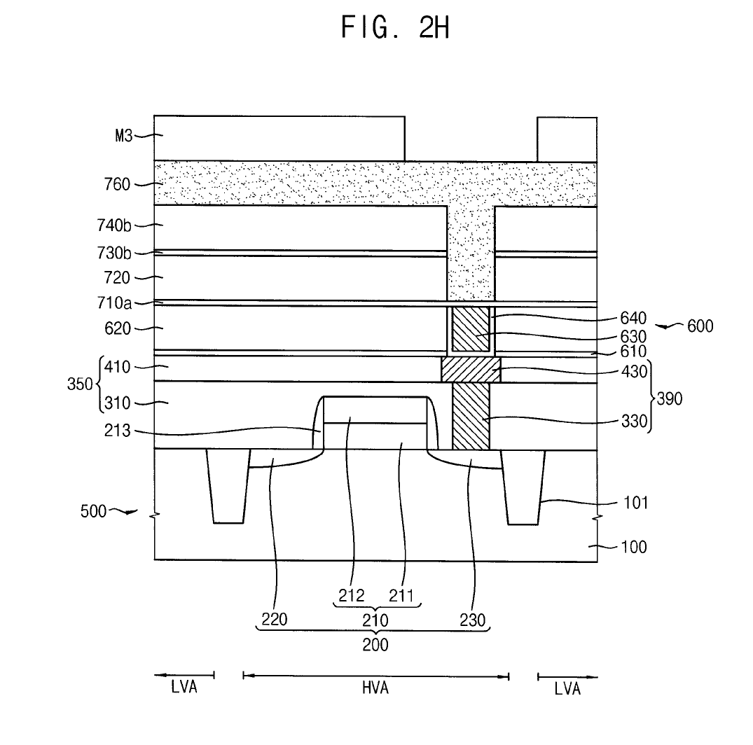

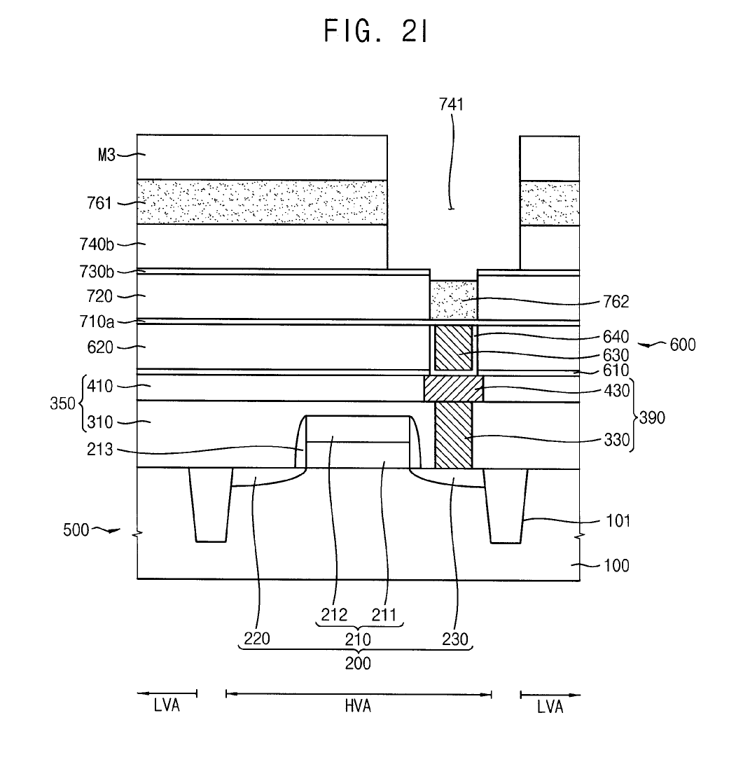

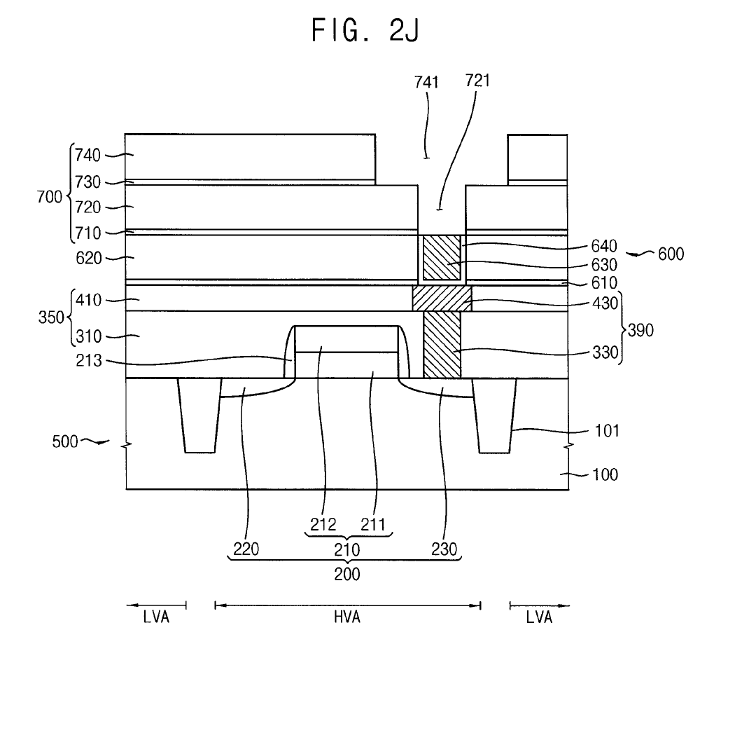

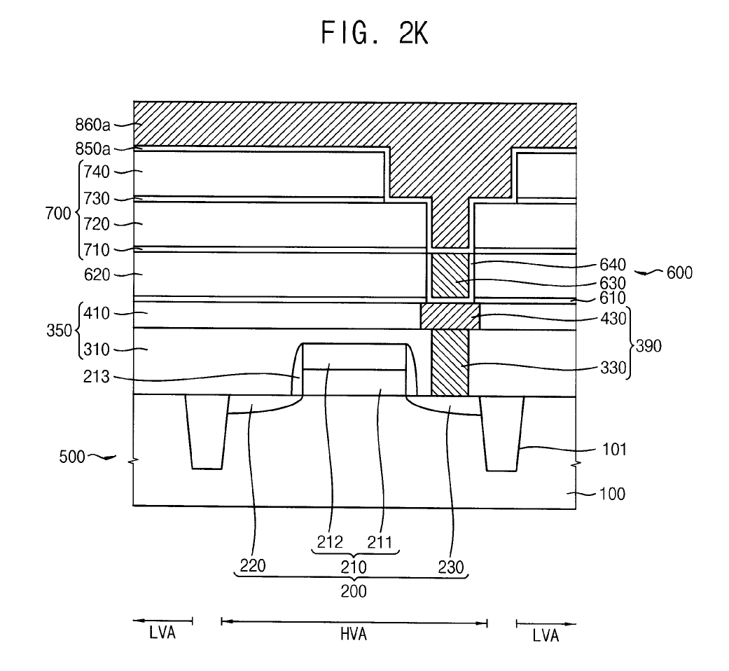

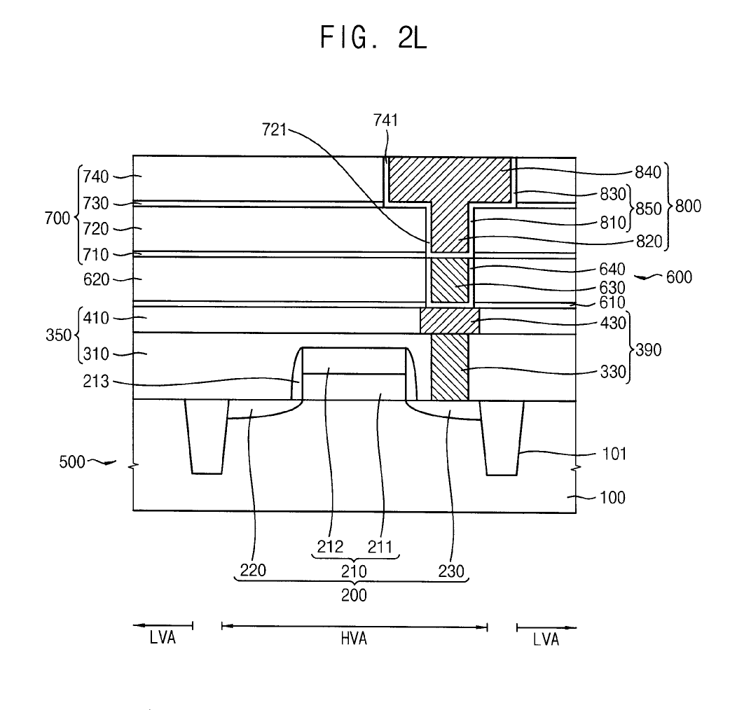

FIGS. 2A to 2L are cross-sectional views illustrating processing steps for method of manufacturing the high voltage device shown in FIG. 1.

Referring to FIG. 2A, the high voltage transistor 200 and the lower wiring 430 connected to the high voltage transistor 200 may be formed on a semiconductor substrate 100, thereby forming the substrate structure 500.

For example, the substrate 100 may include a silicon substrate, a silicon-on-insulator (SOI) substrate, a gallium (Ga)-arsenic (As) substrate, silicon (Si)-germanium (Ge) substrate, ceramic substrate, a quartz substrate and a glass substrate for a flat panel display device.

The substrate 100 may be defined into a high voltage area (HVA) in which high voltage devices may be arranged and a low voltage area (LVA) in which low voltage devices may be arranged. The transistors may be formed on active regions defined by device isolation layers 101 in each of the HVA and LVA of the substrate 100.

A junction termination portion (not shown) may be formed on the substrate 100 between the HVA and the LVA such that the HVA and LVA may be electrically insulated from each other. Thereafter, a plurality of the high voltage transistors 200 and a plurality of low voltage transistors (not shown) may be formed in the HVA and LVA of the substrate 100, respectively. The plurality of the high voltage transistors 200 and the plurality of low voltage transistors may be formed in the same process. In some embodiments, the high voltage transistors 200 may include the high voltage gate structure 210 and the source and drain regions 220 and 230 at surface portions of the substrate 100 adjacent to the high voltage gate structure 210. The high voltage gate structure 210 may include the high voltage gate insulation layer 211 and the high voltage gate conductive layer 212.

In some embodiments, the high voltage gate insulation layer 211 may be formed to be thicker than a gate insulation layer (not shown) of the low voltage transistor such that the high voltage gate structure 210 may sufficiently function as a gate electrode of the high voltage device 1000 although a greater amount of the voltage may be applied to the high voltage device 1000 in the HVA as compared with the low voltage device in the LVA.

Thereafter, the first lower insulation pattern 310 may be formed on the substrate 100 to a sufficient thickness to cover the high voltage gate structure 210. Then, the second lower insulation pattern 410 may be formed on the first lower insulation pattern 310, and then the drain plug 330 and the lower wiring 430 may be formed through the first lower insulation pattern 310 and the second lower insulation pattern 410, respectively. The lower wiring 430 may be formed through the second lower insulation pattern 410 after the drain plug 330 is formed through the first lower insulation pattern 310. Otherwise, the lower wiring 430 and the drain plug 330 may be simultaneously formed through the first and the second lower insulation patterns 310 and 410 by the same process. The first and the second insulation patterns 310 and 410 may constitute a lower insulation pattern 350 and the drain plug 330 and the lower wiring 430 may constitute a lower wiring structure 390.

The drain plug 330 may comprise a conductive material such as doped polysilicon and a low-resistive metal such as tungsten (W), tantalum (Ta) and titanium (Ti). The lower wiring 430 may comprise wiring materials such as copper (Cu) and copper alloy and aluminum (Al) and aluminum alloy. In the present example embodiment, the lower wiring 430 may comprise copper (Cu) in view of low electrical resistance.

Accordingly, the high voltage transistor 200, the lower insulation pattern 350 covering the high voltage transistor 200 and the lower wiring structure 390 making contact with the high voltage transistor 200 through the lower insulation pattern 350 may be formed on the substrate 100, thereby completing the substrate structure 500.

Referring to FIG. 2B, a first etch stop layer 610a, a supplemental insulation layer 620a and a first mask pattern M1 may be sequentially formed on the substrate structure 500.

The first etch stop layer 610a may prevent the lower wiring 430 from being damaged in a subsequent first etching process for forming an opening 621, so that the electrical characteristics of the lower wiring 430 may be protected from the first etching process.

Thus, the first etch stop layer 610a may have an etching selectivity with respect to the supplemental insulation layer 620a. For example, the first etch stop layer 610a may comprise silicon carbide (SiC), silicon nitride (SiN), silicon oxynitride (SiON), boron nitride (BN) and combinations thereof.

In some embodiments, when the lower wiring 430 is formed of copper-based materials, the first etch stop layer 610a may function as an anti-diffusion layer for preventing the copper (Cu) of the lower wiring 430 from being diffused into the supplemental insulation layer 620a.

The supplemental insulation layer 620a may comprise low-k materials and be formed to a sufficient thickness for increasing the dielectric constant of an inter-metal dielectric layer between the upper wiring 840 and the lower wiring 430. Due to the low-k material of the supplemental insulation layer 620a, the signal delay and signal interference may be sufficiently reduced between the lower wiring 430 and the upper wiring 840, thereby decreasing the power consumption of the high voltage device 1000.

In some embodiments, the supplemental insulation layer 620a may comprise low-k organic polymer or oxide doped with impurities. For example, examples of the oxide doped with impurities may include fluorine-doped oxide, carbon-doped oxide, silicon oxide, hydrogen silsesquioxane (HSQ, SiO:H), methyl silsesquioxane (MSQ, SiO:CH3), amorphous hydrogenated silicon oxycarbide (a-SiOC:H), etc. These may be used alone or in combinations thereof. Examples of the low-k organic polymer may include polyallylether polymer, cyclic fluoride polymer, siloxane copolymers, fluorinated polyallylether polymer, polypentafluorostylene polymer, polytetrafluorostylene polymer, fluorinated polyimide polymer, fluorinated polynaphthalene polymer, polycide polymer, etc. These may be used alone or in combinations thereof.

The supplemental insulation layer 620a may be formed on the first etch stop layer 610a by a deposition process or a spin coating process. The deposition process may include a plasma enhanced chemical vapor deposition (PECVD) process, a high-density plasma CVD (HDPCVD) process and an atmospheric pressure CVD (APCVD) process.

The supplemental insulation layer 620a may be formed to a sufficient thickness corresponding to the high voltage applied to the high voltage device 1000. Since the supplemental insulation layer 620a may function as the inter-metal dielectric layer between the upper wiring 840 and the lower wiring 430, the thickness of the supplemental insulation layer 620a may have a critical influence on the dielectric constant of the inter-metal dielectric layer. Therefore, the thickness of the supplemental insulation layer 620a may be determined by considering the high voltage that may be applied to the high voltage device 1000. Thus, the breakdown voltage and leakage currents that may be required with the high voltage device 1000 and the material properties of the supplemental insulation layer 620a.

Thereafter, a hard mask layer (not shown) and a photoresist pattern (not shown) may be sequentially formed on the supplemental insulation layer 620a and then the hard mask layer may be patterned into the first mask pattern M1 by a photolithography process. The supplemental insulation layer 620a may be partially exposed through the first mask pattern M1.

The first mask pattern M1 may include a material having a sufficient etching selectivity with respect to the supplemental insulation layer 620a. For example, the first mask pattern M1 may comprise silicon oxide (SiO2), silicon nitride (SiN), silicon carbide (SiC), benzocyclobutene (BCB), tantalum (Ta), tantalum nitride (TaN), titanium (Ti), titanium nitride (TiN), aluminum oxide (AL2O3), boron nitride (BN) and combinations thereof.

Referring to FIG. 2C, the supplemental insulation layer 620a and the first etch stop layer 610 may be partially removed from the substrate structure 500 by the first etching process, thereby forming an opening 621 through which the lower wiring 430 may be exposed. Thus, the supplemental insulation layer 620a may be patterned into the supplemental insulation pattern 620 and the first etch layer 610a may be patterned into the first etch stop pattern 610.

The supplemental insulation layer 620a may be partially removed from the first etch stop layer 610a until a portion of the first etch stop layer 610a is exposed and then the exposed portion of the first etch stop layer 610a may be removed from the substrate structure 500, thereby forming the opening 621 through which the lower wiring 430 may be exposed.

For example, a first reactive ion etching (RIE) process may be performed on the supplemental insulation layer 620a using the first mask pattern M1 as an etching mask such that the first etch stop layer 610a may remain on the lower wiring 430 and a portion of the supplemental insulation layer 620a may be removed from the substrate structure 500, thereby forming the supplemental insulation pattern 620. Then, a second reactive ion etching (RIE) process may be performed on the first etch stop layer 610a using the first mask pattern M1 and the supplemental insulation pattern 620 as an etching mask such that a portion of the first etch stop layer 610a may be selectively removed from the substrate structure 500, leaving the lower wiring 430 substantially unetched, thereby forming the first etch stop pattern 610.

Referring to FIG. 2D, a first conductive layer 630a may be formed on the supplemental insulation pattern 620 to a sufficient thickness to fill up the opening 621.

For example, a preliminary lower barrier layer 640a may be initially formed on the supplemental insulation pattern 620 along a surface profile of the opening 621. In some embodiments, the preliminary lower barrier layer 640a may be conformally formed on the supplemental insulation pattern 620 having the opening 621. In some other embodiments, the preliminary lower barrier layer 640a may not need to be Then, the first conductive layer 630a may be formed on the preliminary lower barrier layer 640a to a sufficient thickness to fill up the opening 621.

The preliminary lower barrier layer 640a may substantially prevent the conductive materials of the first conductive layer 630a from being diffused into the supplemental insulation pattern 620, thereby preventing the deterioration of the dielectric characteristics of the supplemental insulation pattern 620 due to the diffusion of the conductive materials. In some embodiments, when the first conductive layer 630a is formed of copper (Cu) having good diffusion property, the preliminary lower barrier layer 640a may sufficiently prevent the diffusion of the copper (Cu) to the supplemental insulation pattern 620.

The preliminary lower barrier layer 640a may comprise a conductive metal such as tungsten (W), tantalum (Ta) and titanium (Ti) or a nitride of the conductive metal. For example, the preliminary lower barrier layer 640a may be formed on the supplemental insulation pattern 620 by a physical vapor deposition (PVD) process, a chemical vapor deposition (CVD) process or an atomic layer deposition (ALD) process.

Then, the first conductive layer 630a may be formed on the preliminary lower barrier layer 640a to a sufficient thickness to fill up the opening 621. The first conductive layer 630a may comprise a low resistive material having good electrical conductivity.

For example, the first conductive layer 630a may be formed by a chemical deposition (CVD) process or an electroplating process. Otherwise, the first conductive layer 630a may be formed by performing a sputtering process and a reflow process consecutively. In the case of the electroplating process, a metal seed layer (not shown) may be formed at a bottom of the opening 621 and the conductive materials may be electroplated on the seed layer until the opening 621 is filled up with the conductive materials.

Examples of the low resistive material may include aluminum (Al), copper (Cu), gold (Au), silver (Ag), tungsten (W), molybdenum (Mo), etc. These may be used alone or in combinations thereof.

Referring to FIG. 2E, the first conductive layer 630a may be planarized by a planarization process such as a chemical mechanical polishing (CMP) process, until the first conductive layer 630a just remains in the opening 621, thereby forming the interconnecting linker 630.

For example, the first conductive layer 630 and the preliminary lower barrier layer 640a may be sequentially removed by the CMP process or an etch-back process until an upper surface of the supplemental insulation pattern 620 is exposed. Therefore, the first conductive layer 630a and the preliminary lower barrier layer 640a just remains in the opening 621 to form the interconnecting linker 630 and the lower barrier layer 640.

In the present example embodiment, the first conductive layer 630a may include a single damascene structure that may be formed by an electroplating process and thus may comprise copper (Cu) having relatively high melting point and relatively low specific resistance.

Accordingly, the linker structure 600 including the supplemental insulation pattern 620 and the interconnecting linker 630 may be formed on the substrate structure 500.

Referring to FIG. 2F, an insulation interlayer 700a may be formed on the linker structure 600 and a second mask pattern M2 for exposing the interconnecting linker 630 may be formed on the insulation interlayer 700a.

For example, a first insulation layer 720a may be formed on the linker structure 600 and a second insulation layer 740a may be formed on the first insulation layer 720a. The first and the second insulation layers 720a and 740a may comprise a low-k material as the supplemental insulation pattern 620. In the present example embodiment, the first and the second insulation layers 720a and 740a may comprise the same material as the supplemental insulation pattern 620. However, the first and the second insulation layers 720a and 740a may comprise any other insulating materials as long as the process conditions for forming a via hole and a trench in the first and the second insulation layers 720a and 740a may be sufficiently satisfied. Therefore, the first and the second insulation layers 720 and 740a may comprise insulating materials different from those of the supplemental insulation pattern 620.

The first and the second insulation layers 720a and 740a may be formed by a deposition process such as a plasma enhanced CVD (PECVD) process, a high density plasma CVD (HDPCVD) process and an atmospheric pressure CVD (APCVD) process or a sputtering process.

In some embodiments, the first and the second insulation layers 720a and 740a may be formed to a thickness corresponding to a height of the upper wiring structure 800 that may be formed in a subsequent process. In addition, the first and the second insulation layers 720a and 740a may function as an inter-metal dielectric layer between the upper wiring 840 and the lower wiring 430 such that the total thickness of the first and the second insulation layers 720a and 740a may have a critical influence on the dielectric constant of the inter-metal dielectric layer between the upper wiring 840 and the lower wiring 430. Therefore, the first and the second insulation layers 720a and 740a may be formed to have a proper total thickness in such a way that the first and the second insulation layers 720 and 740 may have a sufficient dielectric constant between the upper wiring 840 and the lower wiring 430 in view of the voltage that may be applied to the high voltage device 1000, the breakdown voltage and leakage current that may be required to the high voltage device 1000 and the material properties of the first and the second insulation layers 720a and 740.

A second etch stop layer 710a may be further formed on the linker structure 600 prior to the formation of the first insulation layer 720a. The second etch stop layer 710a may determine an etching process for forming a via hole in the first insulation layer 720a and may prevent the interconnecting linker 630 from being damaged in the above etching process for forming the via hole. In the same way, a third etch stop layer 730a may be further formed on the first insulation layer 720a prior to the formation of the second insulation layer 740a. The third etch stop layer 730a may determine an etching process for forming a trench in the second insulation layer 740a. In the present example embodiment, the second and the third etch stop layers 710a and 730a may comprise the same materials as the first etch stop layer 640a and may be formed by the same process as performed to the first etch stop layer 640a.

Thereafter, a hard mask layer (not shown) and a photoresist pattern (not shown) may be sequentially formed on the second insulation layer 740a and the hard mask layer may be patterned into the second mask pattern M2 by a photolithography process using the photoresist pattern. Therefore, the second insulation layer 740a may be partially exposed through the second mask pattern M2.

The second mask pattern M2 may have a sufficient etching selectivity with respect to the second insulation layer 740a. For example, the second mask pattern M2 may comprise silicon oxide (SiO2), silicon nitride (SiN), silicon carbide (SiC), benzocyclobutene (BCB), tantalum (Ta), tantalum nitride (TaN), titanium (Ti), titanium nitride (TiN), aluminum oxide (AL2O3), boron nitride (BN) and combinations thereof, just like the first mask pattern M1.

Referring to FIG. 2G, the second insulation layer 740a, the third etch stop layer 730a and the first insulation layer 720a may be partially removed from the linker structure 600 by a second etching process using the second mask pattern M2 as an etching mask, thereby forming a preliminary via hole 750 through which a portion of the second etch stop layer 710a covering the interconnecting linker 630 may be exposed. Therefore, the second insulation layer 740a, the third etch stop layer 730a and the first insulation layer 720a may be patterned into a preliminary second insulation pattern 740b, a preliminary third etch stop pattern 730b and a first insulation pattern 720 by the second etching process.

In some embodiments, the second etching process may be performed until the second etch stop layer 710a is exposed through the preliminary via hole 750, so that the second etch stop layer 710a may terminate the second etching process. Accordingly, the interconnecting linker 630 may be sufficiently prevented from being damaged in the second etching process.

For example, the second etching process may include a reactive ion etching (RIE) process such that the second insulation layer 740a, the third etch stop layer 730a and the first insulation layer 720a may be sufficiently removed, leaving the second etch stop layer 710a substantially unetched.

Referring to FIG. 2H, a sacrificial layer 760 may be formed on the preliminary second insulation pattern 740b to a sufficient thickness to fill up the preliminary via hole 750 and a third mask pattern M3 may be formed on the sacrificial layer 760.

For example, the sacrificial layer 760 may include an inorganic insulation layer having an etching selectivity with respect to the preliminary second insulation pattern 740b, the preliminary third etch stop pattern 730b and the first insulation pattern 720. In the present example embodiment, the sacrificial layer 760 may be formed on the preliminary second insulation pattern 740b by, for example, a sputtering process, and may comprise spin on glass (SOG) and hydrogen silsesquioxane (HSQ). Therefore, the preliminary via hole 750 may be filled up with the sacrificial layer 760 and an upper surface of the sacrificial layer 760 may be planarized by a planarization process.

The third mask pattern M3 may be formed on the sacrificial layer 760 by the same process as the second mask pattern M2. Therefore, the detailed description on the method of forming the third mask pattern M3 will be omitted.

Referring to FIG. 2I, the sacrificial layer 760 and the preliminary third insulation pattern 740b may be partially removed from the substrate structure 600 by a third etching process, using the third mask pattern M3 as an etching mask, until the preliminary third etch stop pattern 730b is exposed, thereby forming a trench 741 through which the preliminary third etch stop pattern 730b may be exposed. In the present example embodiment, the third etching process may include a reactive ion etching (RIE) process as in the second etching process.

Therefore, the trench 741 may be formed to have a width greater than that of the preliminary via hole 750. The preliminary third etch stop pattern 730b may be partially exposed through the trench 741. In addition, the sacrificial layer 760 may be formed into an upper sacrificial pattern 761 that may be formed on the preliminary second insulation pattern 740b and a lower sacrificial pattern 762 that may fill up a lower portion of the preliminary via hole 750. The preliminary second insulation pattern 740b may be formed into the second insulation pattern 740 defining the trench 741.

In some embodiments, the trench 741 may be formed into a line shape having a width greater than that of the preliminary via hole 750 and extending along a predetermined direction.

Referring to FIG. 2J, the upper and the lower sacrificial patterns 761 and 762, portions of the preliminary third etch stop pattern 730b exposed through the trench 741 and a portion of the second etch stop layer 710a covering the interconnecting linker 630 may be sequentially removed from the substrate structure 500, thereby forming a via hole 721 in communication with the trench 741. Thus, the preliminary second insulation pattern 740b may be formed into the second insulation pattern 740 and the second etch stop layer 710a may be formed into the second etch stop pattern 710. That is, the second etch stop pattern 710 may be formed under the first insulation pattern 720 and the third etch stop pattern 730 may be formed under the second insulation pattern 740. The via hole 721 may be defined by the first insulation pattern 720.

In some embodiments, the exposed portions of the preliminary third etch stop pattern 730b in the trench 741 may be removed from the first insulation pattern 720 by an additional dry etch process using the third mask pattern M3 as an etching mask. Then, the third mask pattern M3 may be removed from the upper sacrificial pattern 761 by a stripping process.

Thereafter, the upper and the lower sacrificial patterns 761 and 762 may be removed from the substrate structure 500 by an additional wet etching process. The lower portion of the preliminary via hole 750 that may be filled with the lower sacrificial pattern 762 may be formed into the via hole 721 through which the second etch stop layer 710a may be exposed.

For example, the upper and the lower sacrificial patterns 761 and 762 may be removed from the substrate structure 500 by a wet etching process using a fluorine (F)-contained solution such as a hydrogen fluoride (HF) solution, ammonium fluoride (NH4F) solution and a buffered oxide etchant (BOE) as an etchant.

While the present example embodiment may disclose that the preliminary third etch stop pattern 730b and the second etch stop layer 710a may be separately removed by a respective etching process, the preliminary third etch stop pattern 730b and the second etch stop layer 710a may be removed simultaneously from the substrate structure 500 by the same etching process after removing the upper and the lower sacrificial patterns 761 and 762.

For example, although not illustrated, the second mask pattern M2 may not be removed from the preliminary second insulation pattern 740b. The sacrificial layer 760 may be formed on the second mask pattern M2. Then, the sacrificial layer 760 may be partially removed from the substrate structure 500 by the third etching process using the third mask pattern M3, as described in detail with reference to FIG. 2I. Therefore, in such a case, a sidewall of the second mask pattern M2 may also be exposed in the trench 741. Then, the third mask pattern M3 may be removed from the upper sacrificial pattern 761 such that the upper sacrificial pattern 761 as well as the lower sacrificial pattern 762 may be exposed. Thereafter, the upper and the lower sacrificial patterns 761 and 762 may be removed from the substrate structure 500 by an etching process. As a result, the second mask pattern M2 and the first etch stop layer 710a as well as the preliminary second etch stop pattern 730b may be exposed.

In such a case, the upper and the lower sacrificial patterns 761 and 762 may be removed from the substrate structure 500 by a wet etching process using fluorine (F)-contained solution such as a hydrogen fluoride (HF) solution, ammonium fluoride (NH4F) solution and a buffered oxide etchant (BOE). Otherwise, the upper and the lower sacrificial patterns 761 and 762 may be removed from the substrate structure 500 by a dry etching process using the second mask pattern M2 as an etching mask. In such a case, fluorine (F)-based gases such as CF₄ gases and C₂F₆ gases may be used for the etching gas for the dry etching process.

Then, portions of the preliminary third etch stop pattern 730b, which may be exposed through the trench 741, and portions of the second etch stop layer 710a, which may be exposed through the lower portion of the preliminary via hole 750, may be simultaneously removed by the same reactive ion etching process using the second mask pattern M2 as an etching mask. Thereafter, the second mask pattern M2 may be removed from the preliminary second insulation pattern 740b.

Therefore, the insulation interlayer 700a may be patterned into an insulation interlayer pattern 700 including the second etch stop pattern 710, the first insulation pattern 720, the third etch stop pattern 730 and the second insulation pattern 740. In addition, the trench 741 and the via hole 721 that may be in communication with the trench 741 may be formed through the insulation interlayer pattern 700. The interconnecting linker 630 may be exposed through the via hole 721 and the trench 741.

Referring to FIG. 2K, a preliminary upper barrier layer 850a may be formed on the insulation interlayer pattern 700 along surface profiles of the trench 741 and the via hole 721. In other words, the preliminary upper barrier layer 850a may be conformally formed on the insulation interlayer pattern 700 having the trench 741 and the via hole 721. Then a second conductive layer 860a may be formed on the preliminary upper barrier layer 850a to a sufficient thickness to fill up the trench 741 and the via hole 721.

For example, the preliminary upper barrier layer 850a may comprise a conductive material and may be formed on the insulation interlayer pattern 700 by a physical vapor deposition (PVD) process, a chemical vapor deposition (CVD) process or an atomic layer deposition (ALD) process. Examples of the conductive material of the preliminary upper barrier layer 850a may include tantalum (Ta), tantalum nitride (TaN), tantalum carbide (TaC), titanium (Ti), titanium nitride (TiN), tungsten (W), tungsten nitride (WN), tungsten carbide (WC), titanium silicon nitride (TiSiC), tantalum silicon nitride (TaSiN) and combinations thereof.

The preliminary upper barrier layer 860a may substantially prevent the conductive materials of the second conductive layer 860a from being diffused into the insulation interlayer pattern 700, thereby preventing the deterioration of the dielectric characteristics of the insulation interlayer pattern 700 due to the diffusion of the conductive materials. In some embodiments, when the second conductive layer 860a is formed of copper (Cu) having good diffusion property, the preliminary upper barrier layer 850a may sufficiently prevent the diffusion of the copper (Cu) to the insulation interlayer pattern 700.

For example, the second conductive layer 860a may comprise a low resistive and high conductive metal and may be formed by one of a reflow process, a chemical deposition (CVD) process and an electroplating process. Examples of the low resistive metal may include aluminum (Al), copper (Cu), gold (Au), silver (Ag), tungsten (W), molybdenum (Mo), etc. These may be used alone or in combinations thereof.

In the present example embodiment, the second conductive layer 860a may comprise copper (Cu) having relatively high melting point and relatively low specific resistance and may be formed by an electroplating process. A copper seed layer for the copper electroplating process may be formed on a bottom or a sidewall of the via hole 721 by a PVD process or an ALD process. Then, copper (Cu) may be electroplated on the seed layer until the via hole 721 and the trench 741 is filled with copper (Cu).

Referring to FIG. 2L, the second conductive layer 860a and the preliminary upper barrier layer 850a may be removed from the insulation interlayer pattern 700 by a planarization process until an upper surface of the insulation interlayer pattern 700 is exposed such that the second conductive layer 860a and the preliminary upper barrier layer 850a may just remain in the via hole 721 and the trench 741, thereby forming the upper wiring structure 800. The upper wiring structure 800 may include the upper wiring 840 and the second upper barrier layer 830 in the trench 741 and the via structure 820 and the first upper barrier layer 810 in the via hole 721.

The planarization process for planarizing the second conductive layer 860a may include a chemical mechanical polishing (CMP) process and an etch-back process.

While the present example embodiments discloses that the insulation interlayer pattern 700 and the upper wiring structure 800 may be formed by the via-first dual damascene process in which the via hole 721 is initially formed prior to the trench 741 and the via structure 820 and the upper wiring 840 may be formed together in a single body. However, a trench-first dual damascene process may also be used for forming the insulation interlayer pattern 700 and the upper wiring structure 800 in place of the via-first dual damascene process in which the trench may be initially formed prior to the formation of the via hole.

Further, the via hole 721 and the trench 741 may be separately formed in the insulation interlayer pattern 700, thus the via structure 820 and the upper wiring 840 may also be separately formed in the via hole 721 and the trench 741, respectively. For example, the first insulation pattern 720 and the via structure 820 may be formed on the linker structure 600 by a single damascene process, and the second insulation pattern 740 and the upper wiring 840 may be formed on the first insulation pattern 720 and the via structure 820 by another single damascene process.

According to the above manufacturing method of the high voltage device, a single damascene structure of the linker structure 600 may just be inserted between the upper wiring structure 800 and the substrate structure 500 without any modifications of the conventional processes for forming the upper wiring structure 800. Therefore, the thickness of the inter-metal dielectric layer between the upper wiring 840 and the lower wiring 430 may be sufficiently increased without changing the conventional process conditions for the upper wiring 840. Accordingly, the breakdown voltage and the leakage current characteristics of the high voltage device may be improved without the conventional process conditions for the upper wiring structure.

In some embodiments, the opening 621 for the interconnecting linker 630 may be additionally provided with the high voltage device 1000 by an additional process, the thickness of the inter-metal dielectric layer between the upper wiring and the lower wiring may be increased without any increase of the aspect ratio of the trench and the via hole, thereby sufficiently preventing the process defects such as voids and overhangs of the interconnector between the upper wiring and the lower wiring in spite of the increased thickness of the inter-metal dielectric layer.

Driving Circuit Package Including the High Voltage Device

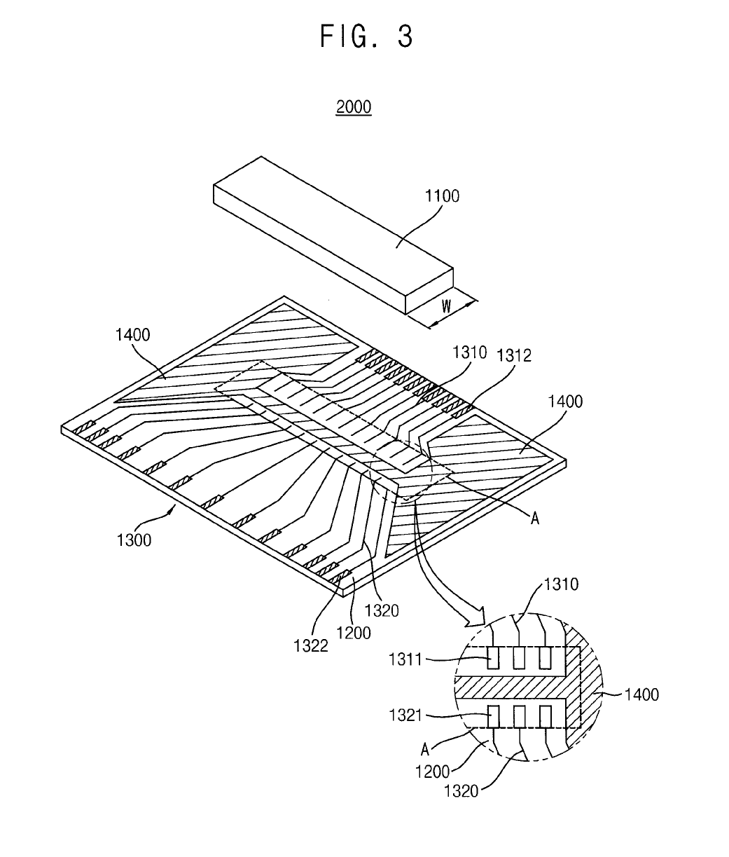

FIG. 3 is a perspective view illustrating a driving circuit package including the high voltage device shown in FIG. 1 in accordance with an example embodiment of the present inventive concept.

In FIG. 3, a display drive integrated circuit (DDI) package for driving a liquid crystal display (LCD) system may be disclosed. However, the disclosure in FIG. 3 is illustrative of a system including the high voltage device shown in FIG. 1 and is not to be construed as limiting thereof and may be applied to various fields. For example, the high voltage device in FIG. 1 may also be applied to a driving unit for a storage system including a plurality of flash memory devices. In addition, the high voltage device in FIG. 1 may be applied to a DDI package for a small display device for a mobile terminal such as a smart phone and a tablet PC as well as the DDI package for a large scale display system such as the liquid crystal display (LCD) and a plasma display panel (PDP) system.

Referring to FIG. 3, a driving circuit package 2000 in accordance with an example embodiment of the present inventive concept may include a drive chip 1100 in which a driving integrated circuit (IC) for driving and controlling a display system, a circuit board 1200 to which the drive chip 1100 may be mounted and a plurality of conductive wirings 1300 arranged on the circuit board and electrically connected with the drive chip 1100 and system resources such as a controller of a main board or a display terminal of the display system. In some embodiments, the driving circuit package 2000 may further include a thermal dissipation pattern 1400 for dissipating the heat from the drive chip 1100 to the external environment.

The drive chip 1100 may include an integrated circuit (IC) chip having a plurality of low voltage device operated under a low driving voltage, and a plurality of high voltage device operated under a high driving voltage. The drive chip 1100 may transmit control signals generated from the main board and may display driving signals to the display terminal and may transfer image signals to the main board from the display terminal.

The high voltage devices in the drive chip 1100 may have substantially the same structure as the high voltage device described in detail with reference to FIG. 1. The thickness of the inter-metal dielectric layer between the upper wiring 840 and the lower wiring 430 may be increased as much as the thickness of the linker structure 600, thus the dielectric constant of the inter-metal dielectric layer between the upper wiring 840 and the lower wiring 430 may be sufficiently increased to such a degree that the breakdown voltage may be greater than a maximal voltage applied to the drive chip 1100. Therefore, the breakdown voltage and the leakage current characteristics of the drive chip 1100 may be improved although a relatively higher voltage may be applied to the drive chip 1100.

In addition, the single damascene structure may be inserted between the upper wiring 840 and the lower wiring 430 as the linker structure 600 without an increase in the aspect ratio of the trench and the via hole. As a result, the vertical length of an interconnector between the upper wiring 840 and the lower wiring 430 may be substantially increased without much process defects such as voids and overhangs. That is, the vertical length of the interconnector between the upper wiring 840 and the lower wiring 430 may be increased without substantial deterioration of the uniformity of the interconnector, thereby increasing the electrical reliability of the driving circuit package 2000.

The circuit board 1200 may include a base film having a thickness of about 20 μm to about 100 μm. The base film may include an insulating film comprising polyiminde resin and polyester resin.

The conductive wirings 1300 may be arranged on the base film as a wiring pattern and may have a line width of about 6 μm to about 8 μm. For example, conductive materials such as tin (Sn), gold (Au), nickel (Ni) and lead (Pb) may be patterned on a copper thin film by an electroplating process, thereby forming the conductive wirings 1300. The conductive wirings 1300 may include first wirings 1310 that may be electrically connected to the main board and second wirings 1320 that may be connected to the display terminal. A first contact portion 1312 may be provided at an end portion of the first wirings 1310 which may be connected with the main board through the first contact portion 1312. A second contact portion 1322 may be provided at an end portion of the second wirings 1320 which may be connected with the display terminal through the second contact portion 1322.

A mounting area A may be provided at a central portion of the metal wirings 1300 and the drive chip 1100 may be positioned at the mounting area A. The mounting area A may be greater than or equal to the size of the drive chip 1100.

A plurality of chip contact terminals may be provided at the mounting area A and the leads of the drive chip 1100 may make contact with the chip contact terminals at the mounting area A. For example, a plurality of first chip contact terminals 1311 may make contact with the first wings 1310, respectively, and a plurality of second chip contact terminals 1321 may make contact with the second wings 1320, respectively. A pair of the first and the second chip contact terminals 1311 and 1321 may face each other and may be spaced by a gap distance corresponding to a width w of the drive chip 1100.

Thus, the drive chip 1100 may be electrically connected with the metal wirings 1300 at the mounting area A. Therefore, the control signals generated from the main board may be applied to the first metal wiring 1310 via the first contact portion 1312 and may be transmitted to the drive chip 1100 via the first chip contact terminal 1311. Driving signals may be generated from the drive chip 1100 according to the control signals may be applied to the second metal wiring 1320 via the second chip contact terminal 1321 and may be transmitted to the display terminal via the second contact portion 1322.

The thermal dissipation pattern 1400 may cover a whole surface of the circuit board 1200 except the metal wirings 1300, and may dissipate the heat from the metal wirings 1300 and the drive chip 1100.

A passivation layer (not shown) may be additionally provided with the driving circuit package 2000, thereby protecting the metal wirings 1300 and the thermal dissipation pattern 1400 from the external environment.

In the present example embodiment, the drive chip 1100 may be mounted on the circuit board by a flip chip bonding process. Thus, the active face of the drive chip 1100 may face downwards and make contact with the first and the second chip contact terminals 1311 and 1321 of the metal wirings 1300.

The above driving circuit package 2000 may be combined with the display terminal such as a liquid crystal panel in various configurations, to thereby constitute a display driving module.

For example, a plurality of gate driving chip packages may be arranged along a first line of the liquid crystal panel for driving the gate lines of the liquid crystal panel and a plurality of data driving chip packages may be arranged along a second line of the liquid crystal panel for driving the data lines of the liquid crystal panel. The gate driving chip package and the data driving chip package may make contact with gate contact pads and data contact pads of the liquid crystal panel, respectively, in a medium of anisotropic conductive films (ACF).

The gate driving chip packages and the data driving chip packages may be connected to the main board such that the control signals for controlling the display system including the liquid crystal panel may be applied to each of the gate and the data driving chip packages. Then, the gate driving chip packages may generate driving signals according to the control signals. The driving signals may be applied to liquid crystal panel. The data driving chip packages may receive the image signals from the liquid crystal panel and may transmit the image signals to the main board according to the control signals.

In such a case, when a relatively high gate voltage for driving the liquid crystal panel may be applied to the gate driving chip package and a relatively high data voltage for receiving the image signals from the liquid crystal panel may be applied to the data driving chip package, the breakdown voltage drop or the leakage currents may be sufficiently prevented in the gate and the data driving chip packages because the dielectric constant of the inter-metal dielectric layer between an upper wiring and a lower wiring of the driving chip may be sufficiently increased due to the linker structure therebetween. Thus, the display system may have improved electrical reliability and stability.

According to the example embodiments of the present inventive concept, the supplemental insulation pattern as well as the insulation interlayer pattern may be interposed between the upper wiring and the lower wiring of the high voltage device. As a result, the thickness of the inter-metal dielectric layer may be sufficiently increased between the upper wiring and the lower wiring. Therefore, although relatively high voltages may be applied to the high voltage device, the high voltage device may sufficiently require the current leakage characteristics and the breakdown voltage characteristics.

In some embodiments, a single damascene structure may be additionally provided between the upper wiring structure and the lower wiring structure through an additional process, the thickness of the inter-metal dielectric layer may be increased between the upper and the lower wiring structures without much change to the conventional processes for forming the upper and the lower wiring structures. Accordingly, the current leakage characteristics and the breakdown voltage characteristics of the high voltage device may be significantly improved without any changes of the conventional processes.

Further, the opening of the supplemental insulation pattern for the interconnecting linker may be additionally provided with the high voltage device by an additional process, the thickness of the inter-metal dielectric layer between the upper wiring and the lower wiring may be increased without a substantial increase in the aspect ratio of the trench and the via hole, thereby sufficiently preventing the process defects such as voids and overhangs of the interconnector making contact with the upper wiring and the lower wiring in spite of the increased thickness of the inter-metal dielectric layer.

The present example embodiments may be applied to high voltage device. However, the present inventive concept may also be applied to various electronic systems having integrated circuit devices. For example, the present inventive concept may be applied to micro-electro mechanical (MEM) devices, photo-electronic devices and display devices with which various minute electronic circuits may be provided. In some embodiments, the present inventive concept may be applied to high speed devices such as a central process units (CPU), digital signal processors (DSP), combinations of the CPU and the DSP, logic devices, static random access memory devices and application specific integrated circuits (ASIC).

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A high voltage device comprising:
a substrate structure having a high voltage transistor and a lower wiring connected to the high voltage transistor;
a linker structure having a supplemental insulation pattern on the substrate structure and an interconnecting linker penetrating through the supplemental insulation pattern and connected to the lower wiring;
an insulation interlayer pattern on the supplemental insulation pattern; and
an upper wiring structure penetrating through insulation interlayer pattern and connected to the interconnecting linker.

2. The high voltage device of claim 1, wherein the supplemental insulation pattern includes an oxide pattern having an opening and the interconnecting linker includes a plug structure disposed in the opening and comprising a conductive metal.

3. The high voltage device of claim 2, wherein the interconnecting linker includes a single damascene structure comprising copper (Cu).

4. The high voltage device of claim 2, further comprising a lower barrier layer interposed between the interconnecting linker in the opening and the supplemental insulation pattern.

5. The high voltage device of claim 1, wherein the insulation interlayer pattern includes a first insulation pattern arranged on the supplemental insulation pattern and has a via hole through which the interconnecting linker is exposed and a second insulation pattern arranged on the first insulation pattern and has a line-shaped trench in communication with the via hole; and
wherein the upper wiring structure includes a via structure disposed in the via hole and contacting the interconnecting linker and an upper wiring disposed in the line-shaped trench and contacting the via structure.

6. The high voltage device of claim 5, wherein the upper wiring structure includes a dual damascene structure in which the via structure and the upper wiring are integrally formed in a single body.

7. The high voltage device of claim 6, wherein the insulation interlayer pattern includes an oxide pattern and the via structure and the upper wiring includes copper (Cu).

8. The high voltage device of claim 5, further comprising an upper barrier layer interposed between the insulation interlayer pattern and the upper wiring structure and between the upper wiring structure and the interconnecting linker.

9. A method of manufacturing a high voltage device, the method comprising:
forming a substrate structure having a high voltage transistor and a lower wiring connected to the high voltage transistor;
forming a linker structure on the substrate structure, the linker structure having a supplemental insulation pattern on the substrate structure and an interconnecting linker penetrating through the supplemental insulation pattern and contacting the lower wiring;
forming an insulation interlayer pattern on the supplemental insulation pattern; and
forming an upper wiring structure that penetrates through the insulation interlayer pattern and makes contact with the interconnecting linker.

10. The method of claim 9, wherein forming the linker structure includes:
forming a supplemental insulation layer on the substrate structure;
partially removing the supplemental insulation layer to form a supplemental insulation pattern having an opening through which at least a portion of the lower wiring is exposed;
forming a first conductive layer on the supplemental insulation pattern to a thickness to fill the opening; and
planarizing the first conductive layer until an upper surface of the supplemental insulation pattern is exposed, leaving a portion of the first conductive layer in the opening.

11. The method of claim 10, prior to forming the first conductive layer on the supplemental insulation pattern, further comprising forming a preliminary lower barrier layer on the supplemental insulation pattern along a surface profile of the opening.

12. The method of claim 10, wherein forming the first conductive layer is performed by one of a reflow process, an electroplating process and a deposition process.

13. The method of claim 10, wherein forming the insulation interlayer pattern includes:
sequentially forming first and second insulation layers on the linker structure;
partially removing the first and the second insulation layers, thereby forming first and second insulation patterns having a preliminary via hole through which at least portion of the interconnecting linker is exposed; and
removing the second insulation pattern around the preliminary via hole, so that the preliminary via hole in the second insulation pattern is formed into a trench having a width greater than the preliminary via hole and the preliminary via hole in the first insulation pattern is formed into a via hole.

14. The method of claim 13, wherein forming the upper wiring structure includes:
forming a preliminary upper barrier layer on the insulation interlayer pattern along a surface profile of the trench and the via hole;
forming a second conductive layer on the preliminary upper barrier to a thickness to fill the via hole and the trench; and
planarizing the second conductive layer until an upper surface of the insulation interlayer pattern is exposed, leaving a portion of the second conductive layer in the via hole and the trench to thereby simultaneously form a via structure in the via hole and an upper wiring in the trench.

15. The method of claim 14, wherein the lower wiring, the interconnecting linker, the via structure and the upper wiring includes one of copper and copper alloy.

16. A semiconductor device comprising:
a substrate comprising a high voltage transistor and a lower wiring connected to the high voltage transistor;
a linker structure comprising a supplemental insulation pattern on the substrate and an interconnecting linker extending through the supplemental insulation pattern and connected to the lower wiring, the interconnecting linker comprising a single damascene structure;
an insulation interlayer pattern on the supplemental insulation pattern; and
an upper wiring structure extending through insulation interlayer pattern and connected to the interconnecting linker.

17. The device of claim 16, wherein the single damascene structure comprises copper.

18. The device of claim 16, wherein the upper wiring structure comprises a dual damascene structure.

19. The device of claim 16, wherein the supplemental insulation pattern comprises low-k organic polymer.

20. The device of claim 16, comprising a barrier layer interposed between the interconnecting linker in the opening and the supplemental insulation pattern, the interconnecting linker being enclosed by the lower barrier layer in the opening.
